(19) United States
(12) Patent Application Publication
(10) Pub. No.: US 2024/0273709 A1
(43) Pub. Date: Aug. 15, 2024

(54) DEVICES AND METHODS OF MANUFACTURING COMPONENT IDENTIFICATION SUCH AS CARTRIDGE IDENTIFICATION

(71) Applicant: NORDSON CORPORATION, WESTLAKE, OH (US)

(72) Inventors: Cutler Crowell, San Marcos, CA (US); Michael Gorman, Oceanside, CA (US); David Padgett, Carlsbad, CA (US)

(73) Assignee: NORDSON CORPORATION, WESTLAKE, OH (US)

(21) Appl. No.: 18/580,771

(22) PCT Filed: Sep. 1, 2022
(86) PCT No.: PCT/US2022/075801

§ 371 Date: Jan. 19, 2024

Related U.S. Application Data
(60) Provisional application No. 63/243,758, filed on Sep. 14, 2021.

(51) Int. Cl. G06T 7/00

(52) U.S. Cl. CPC G06T 7/001; G06T 2207/20081; G06T 2207/20084; G06T 2207/30164

(57) ABSTRACT

A dispensing system for dispensing a fluid material onto a substrate includes a jet dispenser configured to receive the fluid material therein, the jet dispenser having a jet cartridge operably connected thereto, the jet cartridge being configured to receive the fluid material from the jet dispenser and having a nozzle through which the fluid material is discharged towards the substrate; a camera configured to acquire a digital image of the jet dispenser; and a controller having a memory and a processor. The processor is configured to: identify, on the digital image of the jet dispenser, an identified pattern of features present on the jet dispenser; compare the identified pattern with a stored pattern, the stored pattern being stored in the memory; calculate the similarity between the identified pattern and the stored pattern; and provide an identifier value associated with the stored pattern.

### CROSS-REFERENCE TO RELATED APPLICATION

This application is a National Stage Application of International Patent App. No. PCT/US2022/075801, filed Sep. 1, 2022, which claims the benefit of U.S. Provisional Patent App. No. 63/243,758, filed Sep. 14, 2021, the entire disclosures of both of which are hereby incorporated by reference as if set forth in their entirety herein.

### TECHNICAL FIELD

The disclosure relates generally to manufacturing systems, and more particularly to identification of components in manufacturing systems. Further, the disclosure relates generally to fluid dispensers, and more particularly to identification of components in fluid dispensers. More specifically, the disclosure relates generally to fluid dispensers, and more particularly to identification of cartridges in fluid dispensers.

### BACKGROUND

Manufacturing systems are implemented to produce and/or modify products, such as substrates, with various equipment, components, and/or the like. For example, manufacturing systems may include non-contact viscous material dispensers that are sometimes used to apply viscous materials onto substrates. The non-contact viscous material dispensers may include equipment, components, and/or the like, such as cartridges, implemented in a manufacturing line. The process control on the manufacturing line is very important. For example, being able to account and adjust for slight variations in equipment of the non-contact viscous material dispensers, such as the cartridges, allows the continued manufacture of good parts under a variety of different circumstances. In this regard, it would be beneficial to track information for particular equipment that is being used at any given time. Tracking this information would allow one to determine the life of a particular piece of equipment, which information could be utilized to determine to remove the particular piece of equipment from service once the particular piece of equipment has exceeded a recommended use. However, there is currently no good way of identifying and tracking individual pieces of equipment of the manufacturing system, such as non-contact viscous material dispensers.

Therefore, a need exists for mechanisms and methods of efficiently identifying individual pieces of equipment being used in manufacturing system, such as non-contact viscous material dispensers.

### SUMMARY

The foregoing needs are met by various aspects of components, such as jet dispensers, and manufacturing systems, such as dispensing systems, as disclosed. According to an aspect of this disclosure, a jet dispenser identification system includes a camera configured to acquire a digital image of a jet dispenser and a controller having a memory and a processor. The processor is configured to: identify, on the digital image of the jet dispenser, an identified pattern of features present on the jet dispenser: compare the identified pattern with a stored pattern, the stored pattern being stored in the memory: calculate a similarity between the identified pattern and the stored pattern; and provide an identifier value associated with the stored pattern.

Optionally, the identifier value may include at least one of the following associated with the jet cartridge: a product name, a product type, a product serial number, a product number, and a product manufacturing lot number.

Optionally, the processor may be configured to compare the identified pattern with a plurality of stored patterns and calculate the similarity between the identified pattern and each of the plurality of stored patterns, the processor being further configured to select one of the plurality of stored patterns, the one of the plurality of stored patterns being most similar to the identified pattern out of the plurality of stored patterns.

Optionally, the processor may be configured to implement a neural network to compare the identified pattern with a plurality of stored patterns and calculate the similarity between the identified pattern and each of the plurality of stored patterns, the processor being further configured to implement the neural network to select one of the plurality of stored patterns, the one of the plurality of stored patterns being most similar to the identified pattern out of the plurality of stored patterns.

Optionally, the system can be configured to be in wired communication with a jet dispenser configured to receive a fluid material therein. Alternatively, the system can be configured to be in wireless communication with a jet dispenser configured to receive a fluid material therein.

According to another aspect, a dispensing system for dispensing a fluid material onto a substrate can include a jet dispenser configured to receive the fluid material therein. The jet dispenser can have a jet cartridge operably connected thereto, The jet cartridge can be configured to receive the fluid material and having a nozzle configured to discharge the fluid material. The dispensing system can further have a jet dispenser identification system that has a camera configured to acquire a digital image of a jet dispenser and a controller having a memory and a processor. The processor is configured to: identify, on the digital image of the jet dispenser, an identified pattern of features present on the jet dispenser: compare the identified pattern with a stored pattern, the stored pattern being stored in the memory: calculate a similarity between the identified pattern and the stored pattern; and provide an identifier value associated with the stored pattern.

According to another aspect of this disclosure, a method of training a neural network to identify a component out of a stored list of components is disclosed. The neural network is stored on a memory of a controller and operable by a processor on the controller. The method includes: introducing a first component to an input device in electronic communication with the controller, the first component having a first feature thereon: associating, via the processor, the first feature with a first identifier associated with the first component: storing an association of the first feature with the first identifier in the memory: introducing a second component to the input device, the second component having a second feature: associating, via the processor, the second feature with a second identifier associated with the second component; and storing an association of the second feature with the second identifier in the memory.

Optionally, the input device can include a camera configured to acquire a digital image of the first and second components.

Optionally, the first and second identifiers may include at least one of the following associated with the first and second components: product names, product types, product serial numbers, product numbers, and product manufacturing lot numbers.

Optionally, the method can include introducing a third component to the input device, the third component having a third feature: comparing the third feature of the third component to the first feature of the first component and to the second feature of the second component; and receiving a prediction from the processor of which of the first component and the second component is more similar to the third component.

Optionally, the method can include indicating to the processor whether the prediction is correct.

According to another aspect, a method of identifying a jet cartridge in a dispensing system is disclosed. The dispensing system includes the jet cartridge, a camera, and a controller having a processor and a memory. The method includes: actuating the camera to acquire an image of the jet cartridge: identifying a pattern of features on the jet cartridge that are visible on the acquired image: comparing the identified pattern with a plurality of stored patterns in the memory: actuating the processor to select one of the plurality of stored patterns, the selected one of the plurality of stored patterns being most similar to the identified pattern out of the plurality of stored patterns; and displaying an identifier associated with the selected one of the plurality of stored patterns.

Optionally, the method can include displaying a measurement of similarity between the identified pattern and the selected one of the plurality of stored patterns.

Optionally, the identifier may include at least one of the following: a product name, a product serial number, a product number, and a product manufacturing lot number.

Optionally, the pattern of features can include a barcode.

Optionally, the comparing and the actuating step may include implementing a neural network.

Optionally, the method may include displaying an accuracy value associated with the identifier.

According to another aspect of this disclosure, a manufacturing system for dispensing a fluid material includes a dispenser configured to receive the fluid material therein. The dispenser can have a dispenser component operably connected thereto, the dispenser component being configured to receive the fluid material from the dispenser and having a nozzle configured to discharge the fluid material therethrough. The manufacturing system further includes a camera configured to acquire a digital image of the dispenser; and a controller having a memory and a processor. The processor is configured to: identify, on the digital image of the dispenser, an identified pattern of features present on the dispenser: compare the identified pattern with a stored pattern, the stored pattern being stored in the memory: calculate a similarity between the identified pattern and the stored pattern; and provide an identifier value associated with the stored pattern.

Optionally, the identifier value may include at least one of the following associated with the dispenser component: a product name, a product type, a product serial number, a product number, and a product manufacturing lot number.

Optionally, the processor may be configured to compare the identified pattern with a plurality of stored patterns and calculate the similarity between the identified pattern and each of the plurality of stored patterns. The processor may be configured to select one of the plurality of stored patterns, the one of the plurality of stored patterns being most similar to the identified pattern out of the plurality of stored patterns.

Optionally, the processor may be configured to implement a neural network to compare the identified pattern with a plurality of stored patterns and calculate the similarity between the identified pattern and each of the plurality of stored patterns. The processor may be configured to implement the neural network to select one of the plurality of stored patterns, the one of the plurality of stored patterns being most similar to the identified pattern out of the plurality of stored patterns.

According to yet another aspect of the disclosure, a method of training a neural network to identify a component out of a stored list of components is disclosed. The neural network is stored on a memory of a controller and operable by a processor on the controller. The method includes: introducing a first component to an input device in electronic communication with the controller, the first component having a first feature thereon: associating, via the processor, the first feature with a first identifier associated with the first component: storing the association of the first feature with the first identifier in the memory: introducing a second component to the input device, the second component having a second feature: associating, via the processor, the second feature with a second identifier associated with the second component; and storing the association of the second feature with the second identifier in the memory.

Optionally, the input device may include a camera configured to acquire a digital image of the first and second components.

Optionally, the first and second identifiers may include at least one of the following associated with the first and second components: product names, product types, product serial numbers, product numbers, and product manufacturing lot numbers.

Optionally, the method may include: introducing a third component to the input device, the third component having a third feature: comparing the third feature of the third component to the first feature of the first component and to the second feature of the second component; and receiving a prediction from the processor of which of the first component and the second component is more similar to the third component.

Optionally, the method may include indicating to the processor whether the prediction is correct.

According to yet another aspect of the disclosure, a method of identifying a dispenser component in a manufacturing system is disclosed. The manufacturing system includes the dispenser component, a camera, and a controller having a processor and a memory. The method includes: actuating the camera to acquire an image of the dispenser component: identifying a pattern of features on the dispenser component that are visible on the acquired image: comparing the identified pattern with a plurality of stored patterns in the memory: actuating the processor to select one of the plurality of stored patterns, the selected one of the plurality of stored patterns being most similar to the identified pattern out of the plurality of stored patterns; and displaying an identifier associated with the selected one of the plurality of stored patterns.

Optionally, the method may include displaying a measurement of similarity between the identified pattern and the selected one of the plurality of stored patterns.

Optionally, the identifier may include at least one of the following: a product name, a product type, a product serial number, a product number, and a product manufacturing lot number.

Optionally, the pattern of features may include a barcode.

Optionally, the comparing and the actuating may include implementing a neural network.

Optionally, the method may include displaying an accuracy value associated with the identifier.

### BRIEF DESCRIPTION OF THE DRAWINGS

The present application is further understood when read in conjunction with the appended drawings. For the purpose of illustrating the subject matter, there are shown in the drawings exemplary aspects of the subject matter; however, the presently disclosed subject matter is not limited to the specific methods, devices, and systems disclosed. In the drawings:

FIG. 1 depicts a side view of a dispensing system according to an aspect of this disclosure;

FIG. 2 depicts a perspective view of the jet dispenser of FIG. 1:

FIG. 3 depicts a perspective view of a jet cartridge according to an aspect of this disclosure:

FIG. 4 depicts a bottom view of the jet cartridge of FIG. 3:

FIG. 5 depicts a perspective view of a portion of the jet cartridge of FIG. 3:

FIG. 6 depicts a cross-sectional view of a portion of a jet dispenser according to an aspect of this disclosure:

FIG. 7A depicts an image of a bottom view of a portion of a jet cartridge according to an aspect of this disclosure:

FIG. 7B depicts an image of a bottom view of a portion of another jet cartridge according to an aspect of this disclosure:

FIG. 7C depicts an image of a bottom view of a portion of yet another jet cartridge according to an aspect of this disclosure:

FIG. 8 depicts a schematic of a dispensing system according to an aspect of this disclosure:

FIG. 9 depicts a schematic of a learning module according to an aspect of this disclosure:

FIG. 10 depicts a schematic of an operating module according to an aspect of this disclosure:

FIG. 11 depicts a flow chart schematic of the learning module of FIG. 9;

FIG. 12 depicts a flow chart schematic of the operating module of FIG. 10:

FIG. 13 depicts a flow chart of a training process according to an aspect of this disclosure; and

FIG. 14 depicts a flow chart of an operating process according to an aspect of this disclosure.

Aspects of the disclosure will now be described in detail with reference to the drawings, wherein like reference numbers refer to like elements throughout, unless specified otherwise.

### DETAILED DESCRIPTION OF ILLUSTRATIVE EMBODIMENTS

Components of a manufacturing system, such as a cartridge, may have visible features on the components, such as the face of its nozzle. For example, the visible features may include machine marks, other slight imperfections, and/or the like that may be used by a neural network to recognize and identify the exact component, such as a cartridge, to which they belong. In particular, it was found that using deep neural networks and image recognition could determine if a nozzle was clean or dirty. Additionally, it was realized that with proper lighting, magnification, and/or the like that slight variations on the surface of each component, such as a cartridge's nozzle, may become visible. For example, slight variations such as machine marks, changes in brightness, slight imperfections, etc. Further, it was determined that these slight variations may be used to teach a deep neural network to identify the exact component, such as cartridge, being used, which may be a component fingerprint, a component facial recognition, and/or the like. For machines with a lookup camera installed, this may be an effective way of identifying, tracking, and/or the like component use, such as cartridge use, which would be a distinct advantage for users. Additionally, the disclosed system may also potentially be used to identify new physical defects in a component, such as on the nozzle face. For example, physical defects such as a chipped nozzle, otherwise damaged cartridge face, and/or the like.

Aspects of the disclosure relate generally to manufacturing systems, and more particularly to identification of components in manufacturing systems. For example, the disclosure relates generally to fluid dispensers. Non-contact viscous material dispensers are sometimes used to apply viscous materials onto substrates. For example, non-contact viscous material dispensers are sometimes used to apply minute amounts of viscous materials, i.e., those with a viscosity exceeding fifty centipoise, onto substrates. As used herein, “non-contact” means where the jetting dispenser does not contact the substrate during the dispensing process. For example, non-contact jetting dispensers can be used to apply various viscous materials onto electronic substrates such as printed circuit boards. Viscous materials applied to electronic substrates may include, by way of example and not by limitation, general purpose adhesives, solder paste, solder flux, solder mask, thermal grease, lid sealant, oil, encapsulants, potting compounds, epoxies, die attach fluids, silicones, room temperature vulcanizing (RTV) materials, cyanoacrylates, and/or other suitable materials.

In semiconductor package assembly, applications exist for underfilling, solder ball reinforcement in ball grid arrays, dam and fill operations, chip encapsulation, underfilling chip scale packages, cavity fill dispensing, die attach dispensing, lid seal dispensing, no flow underfilling, flux jetting, dispensing thermal compounds, among other uses. For surface-mount technology (SMT), printed circuit board (PCB) production, and/or the like, surface mount adhesives, solder paste, conductive adhesives, solder mask materials, and/or the like may be dispensed from non-contact dispensers, as well as selective flux jetting.

Jetting dispensers can contain either pneumatic or electric actuators for moving a shaft, tappet, and/or the like repeatedly toward a seat while jetting a droplet of viscous material from an outlet orifice of the dispenser. The electrically actuated jetting dispensers can, more specifically, use a piezoelectric actuator. Precisely jetting fluids using a valve closure structure contacting a valve seat can require that the shaft be brought into contact with the valve seat using a prescribed stroke (displacement) and velocity to effectively eject a dot of fluid material from the outlet of the nozzle. The displacement and velocity curve collectively form the motion profile.

Jet dispensers can generally operate to dispense small volumes of fluid material to a substrate by rapidly impacting a valve seat with a valve member to create a distinct, high pressure pulse that ejects a small volume, or droplet, of fluid material from the nozzle of the dispenser, which flies from the nozzle through the air to impact a surface, or substrate, onto which the fluid material is being applied.

The valve member and nozzle can be housed in a jet cartridge that is designed to be used with such jet dispensers. The cartridges can be manufactured to specific proportions and tolerances. The cartridges can include different materials and can be manufactured using different tools and processes. Thus, various types of cartridges that can be used interchangeably with jet dispensers and can have various distinctions.

The disclosure relates generally to manufacturing systems, and more particularly to identification of components in manufacturing systems. However, for brevity, the disclosure will be described in relation to fluid dispensers, and more particularly to identification of cartridges in fluid dispensers. However, aspects of the disclosure may be applicable to numerous other applications, implementations, and/or the like.

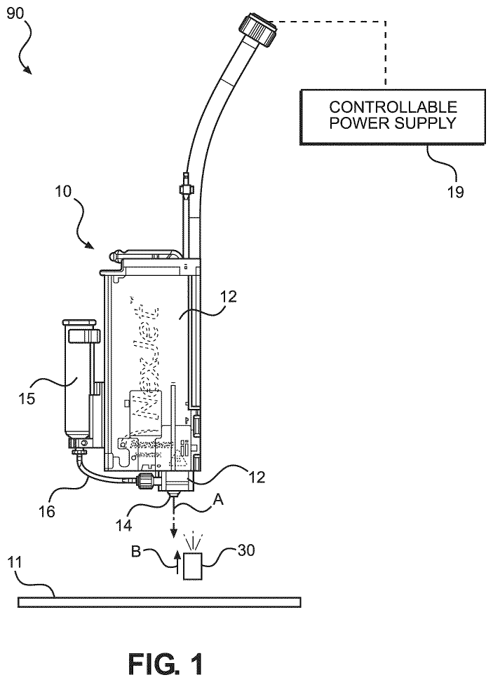

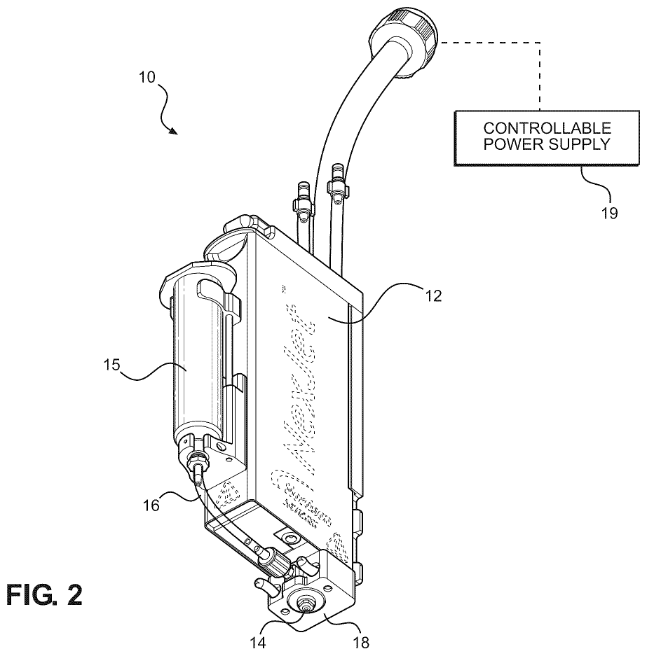

Referring to FIGS. 1 and 2, a dispensing system 90 is depicted having a jet dispenser 10 in accordance with an embodiment of the disclosure. The jet dispenser 10 may include an actuator 12, a jet cartridge 14 operatively coupled to the actuator 12, and a fluid reservoir 15 adapted to supply fluid material to the jet cartridge 14 through a fluid feed tube 16. The fluid material may include various heat-sensitive fluid materials, such as epoxy, silicone, other adhesives having a temperature-dependent viscosity, and/or the like.

The jet dispenser 10 may be configured to discharge the fluid material towards a substrate 11. The fluid material can be discharged in various ways and/or patterns. For example, the fluid material can be poured, dripped, forcefully pushed or jetted, and/or the like. In some aspects, the fluid material can be ejected out of the jet dispenser 10 forcefully (i.e. “jetted”), in which scenarios a droplet of the fluid material disengages from the jet dispenser 10 before making contact with the substrate 11. Thus, in a jetting type dispenser, the droplet dispensed is “in-flight” between the jet dispenser 10 and the substrate 11, and not in contact with either the jet dispenser 10 or the substrate 11 for at least a part of the distance between the jet dispenser 10 and the substrate 11. In other types of applications, discrete jetted droplets of material can remain connected to the jet dispenser 10 (e.g., via a thin strand of material) while the droplet is moved toward the substrate 11. In further aspects, each subsequent droplet may be connected to a preceding and/or subsequent droplet. Such jetting dispenser embodiments can be used to dispense fluid materials that include, but are not limited to, underfill materials, encapsulation materials, surface mount adhesives, solder pastes, conductive adhesives, solder mask materials, fluxes, thermal compounds, and/or the like.

The jet dispenser 10 can further include a heating element 18 configured to provide heat to the fluid material while the fluid material is in the jet dispenser 10. The heating element 18 may include a heater and/or a heating coil, such as an electronic heater, a radiator heater, a convection heater, and/or the like. At least a portion of the heating element 18 can be disposed adjacent to the jet cartridge 14, such that at least a portion of the jet cartridge 14 contacts the heating element 18. The heating element 18 can be powered by a controllable power supply 19 to maintain an optimal temperature and viscosity of the fluid material during operation.

During use, the actuator 12 is operable to actuate a valve member (not shown) within the jet cartridge 14 to allow the fluid material to be dispensed from the jet dispenser 10 towards the substrate 11. In some aspects, the actuator 12 may be configured to move the valve member to open a passage through the jet cartridge 14 through which the fluid material may flow out of the jet dispenser 10. The fluid material may flow due to gravity, fluid pressure, air pressure, mechanical pressure, and/or the like acting on the fluid material. In some aspects, the fluid material can be forcefully ejected, jetted, and/or the like, from the jet cartridge 14 onto the substrate 11. In such aspects, the actuator 12 may be configured to move the valve member towards and through the fluid material within the jet cartridge 14 to contact and forcefully push at least a portion of the fluid material in the jet cartridge 14 out of the jet cartridge 14 towards the substrate 11.

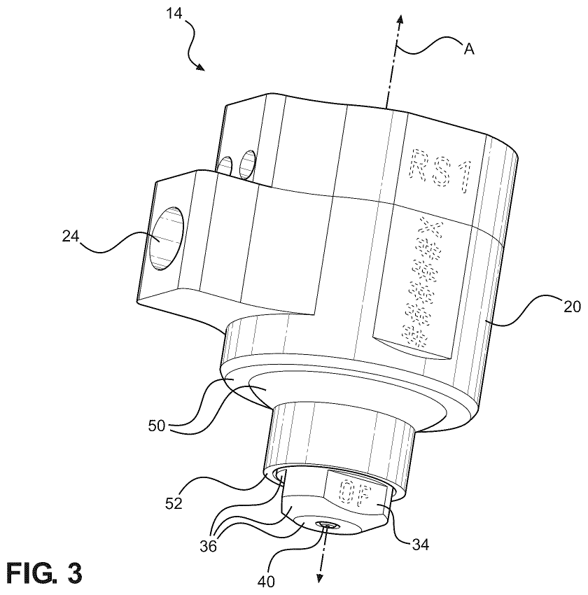

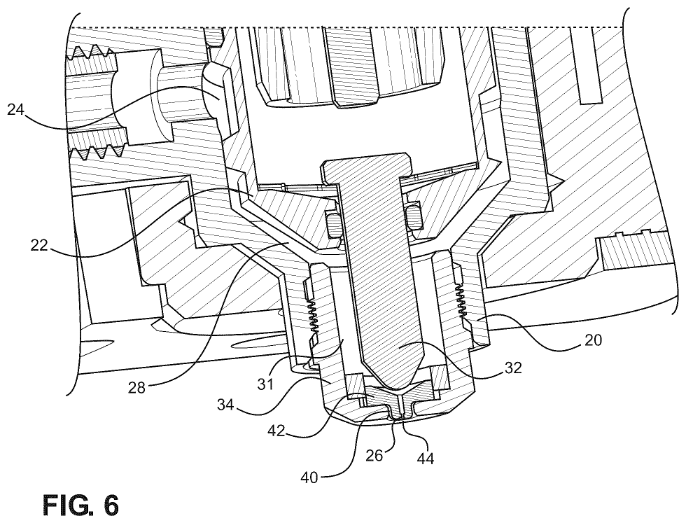

Referring to FIGS. 3-6, an exemplary jet cartridge 14 is depicted. It will be appreciated that other jet cartridges can be used with the jet dispenser 10. The jet cartridge 14 may be removably secured to the jet dispenser 10 and may be releasable and removable from the jet dispenser 10. In some aspects, the jet dispenser 10 may be configured to selectively receive and operate with different types of the jet cartridges 14 and/or a plurality of the same types of the jet cartridge 14.

The jet cartridge 14 can include an outer cartridge body 20 and a flow insert (not shown) configured to be received in or on the outer cartridge body 20. The outer cartridge body 20 and the flow insert may be formed of any suitable heat-resistant material, such as 303 stainless steel for example. The jet cartridge 14 may include a fluid inlet 24, through which the fluid material is configured to be received into the jet cartridge 14. The jet cartridge 14 may further include a fluid outlet 26, through which the fluid material can be discharged out of the jet cartridge 14, for example, toward the substrate 11. A fluid passage can be defined within the jet cartridge 14 between the fluid inlet 24 and the fluid outlet 26. It will be appreciated that the jet cartridge 14 may include a plurality of fluid passages. The fluid passage may include various different shapes, and this disclosure is not limited to a particular fluid passage shape or orientation. For example, the fluid passage may be linear or curved. The fluid passage may include a first portion 22 and a second portion 28 that is angularly offset from the first portion 22. The fluid passage may extend circumferentially around the jet cartridge 14, for example, about a dispensing axis A (shown in FIG. 3). In some aspects, the fluid passage may include a spiral shape and may extend helically along the dispensing axis A.

A fluid chamber 31 can be defined in the jet cartridge 14 between the fluid inlet 24 and the fluid outlet 26. The fluid chamber 31 may be configured to receive the fluid material from the fluid inlet 24. The fluid chamber 31 can be in fluid communication with the fluid passage. In some aspects, the fluid passage can include the fluid chamber 31.

The jet cartridge 14 can include a nozzle 40 through which the fluid material is configured to pass upon being discharged from the jet cartridge 14. The nozzle 40 can be disposed on, in, or adjacent to at least one of the outer cartridge body 20 and the flow insert. The nozzle can include a nozzle body 42 and a nozzle tip 44 extending from the nozzle body 42. In some aspects, at least a portion of the nozzle body 42 may be disposed within the jet cartridge 14, and at least a portion of the nozzle tip 44 may be disposed outside of the jet cartridge 14.

In some aspects, the jet cartridge 14 may include a nozzle hub 34 configured to receive the nozzle 40 thereon or therein. The nozzle hub 34 can be secured to the jet cartridge 14, for example, to the outer cartridge body 20. The nozzle body 42 may be disposed within the nozzle hub 34, and the nozzle tip 44 may extend out of the nozzle hub 34.

The fluid outlet 26 may be defined on or through the nozzle 40. During operation, the actuator 12 can actuate movement of the valve member 32 within and through the fluid chamber 31 toward the nozzle 40. During such movement, the valve member 32 can contact the fluid material in the fluid chamber 31 and force at least a portion thereof towards the nozzle 40 and out through the fluid outlet 26.

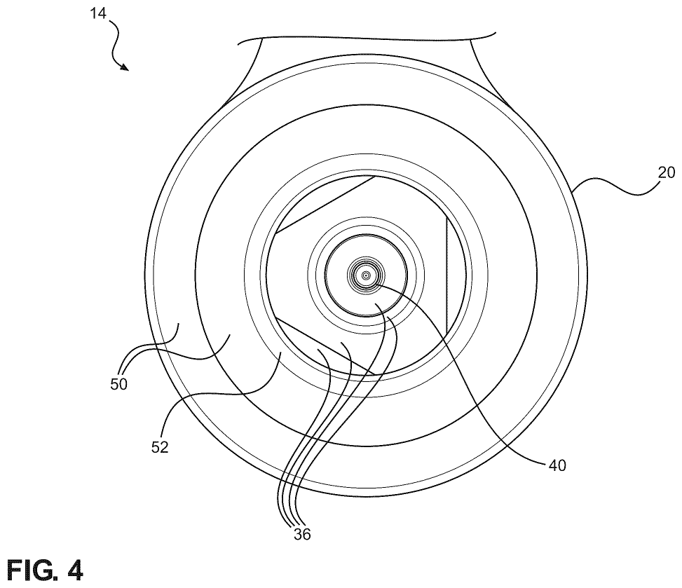

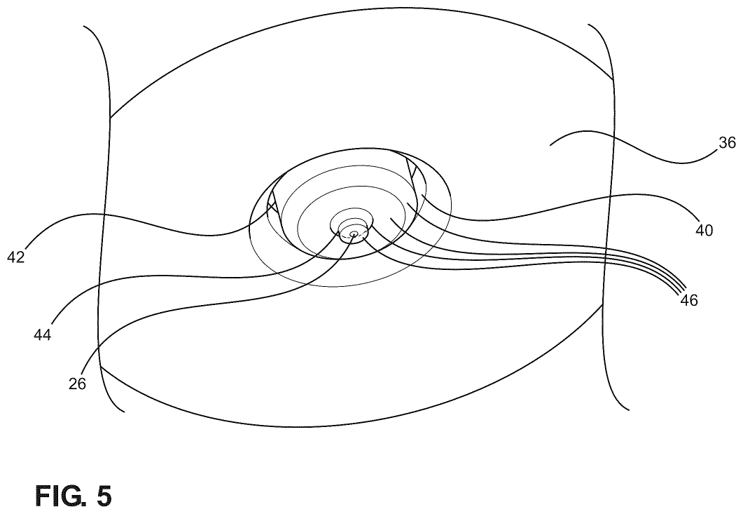

The outer cartridge body 20 can define a surface 50, at least a portion of the surface 50 may be orthogonal to the dispensing axis A (see FIG. 3). The outer cartridge body 20 can define a distal surface 52 at a distal end of the outer cartridge body 20. At least a portion of the distal surface 52 can be orthogonal to the dispensing axis A. The nozzle hub 34 can include a plurality of surfaces 36 defined thereon, at least a portion of each of the plurality of surfaces 36 being orthogonal to the dispensing axis A. Referring to FIG. 5, the nozzle 40 can define one or more surfaces 46, with at least a portion of each of the one or more surfaces 46 being orthogonal to the dispensing axis A. One or more surfaces 46 may be disposed on the nozzle body 42, on the nozzle tip 44, or on both, the nozzle body 42 and the nozzle tip 44

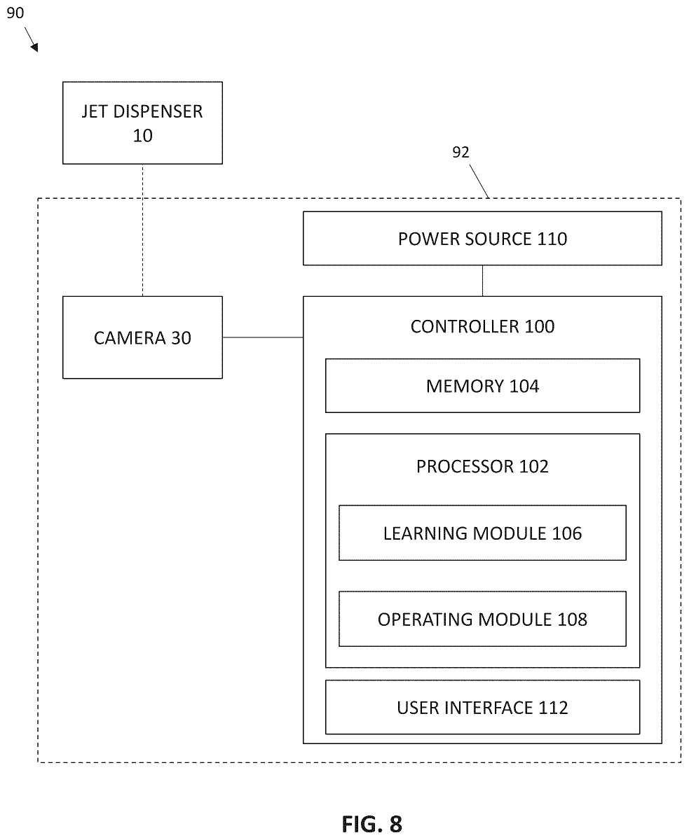

A jet dispenser identification system 92 (see FIG. 8) can be utilized to observe the jet dispenser 10 (or another jet dispenser) for on-line or off-line identification. One or more characteristics of the jet dispenser 10 can be detected and/or measured by the jet dispenser identification system 92. In some embodiments, the jet dispenser identification system 92 can be physically connected to the jet dispenser 10 or can be wirelessly connected to the jet dispenser 10. In some aspects, the jet dispenser identification system 92 can receive information from the jet dispenser 10 during operation of the jet dispenser 10. Alternatively, the jet dispenser identification system 92 can be configured to receive information prior to or after operation of the jet dispenser 10. The jet dispenser identification system 92 can be configured to receive information from a plurality of jet dispensers 10 or other suitable jet dispensers.

A camera 30 may be used to observe the jet dispenser 10 (see FIG. 1). The camera 30 may be attached to the jet dispenser 10 or may be physically separated from the jet dispenser 10. The camera 30 may be directed to optically capture images and/or video of at least a portion of the jet dispenser 10 and/or the substrate 11. The camera 30 may be directed along a camera direction B (see FIG. 1). The camera direction B may be parallel to the dispensing axis A. It will be appreciated that the camera 30 may have a suitable viewing angle that defines a viewing area that the camera 30 can capture. The camera direction B can include any direction from the camera 30 within the viewing area. Additionally, the camera 30 may have a support structure configured to move the camera 30 into position along one or more multiple axes, rotate the camera 30 about one or more multiple axes, and/or the like. The support structure may include various motors, controllers, gantries, carriages, and/or the like to arrange the camera 30 and an operative position, and an operative position, and/or the like. The jet dispenser identification system 92 can include the camera 30.

The camera 30 can be configured to optically capture and/or record visual data before, during, and/or after operation of the jet dispenser 10. The camera 30 can include one or more separate cameras. The camera 30 may include a charge coupled device (CCD), CMOS (complementary metal-oxide-semiconductor) image sensors, Back Side Illuminated CMOS, and/or the like. Images captured by the camera 30 may be converted and stored in various formats including a JPEG (Joint Photographic Experts Group) file format, a TIFF (Tag Image File Format) file format, RAW feature format, and/or the like. The camera 30 may include a lens, optics, lighting components, and/or the like as well as the controller for controlling the same. The camera 30 can be directed at the jet dispenser 10, with at least a portion of the direction of the camera 30 being parallel to the dispensing axis A. The camera 30 can be configured to visually view the jet cartridge 14. In some aspects, the camera 30 may be configured to view the outer cartridge body 20, the nozzle hub 34, the nozzle 40, and/or like.

The camera 30 may be arranged to view the jet dispenser 10 such that a viewing angle of the camera 30 includes a portion thereof that is substantially parallel to the dispensing axis A (i.e., along the camera direction B). That is, the images and/or video viewed and/or recorded by the camera 30 can be captured in a direction parallel to the dispensing axis A. The camera 30 may view one or more surfaces of the jet cartridge 14 described above, such as one or more of the surfaces 50 of the outer cartridge body 20, one or more distal surfaces 52 of the outer cartridge body 20, one or more surfaces 36 of the nozzle hub 34, one or more surfaces 46 on the nozzle 40, and/or other surfaces of the jet cartridge 14 and/or the rest of the jet dispenser 10.

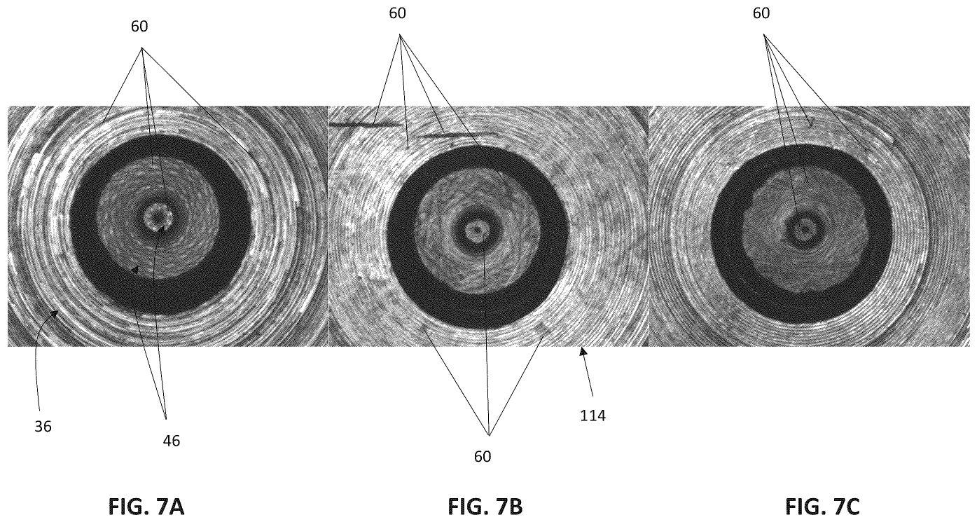

The jet cartridge 14 can include a feature thereon that can be observed by the camera 30. The feature can be disposed in the jet cartridge 14 or, alternatively, on the jet cartridge 14. The feature can include a marking caused by the machining process during manufacture of the jet cartridge 14, damage caused to the jet cartridge 14 during use, dirt or accumulation of a material on the jet cartridge 14, and/or the like. In various aspects, the feature can be a shape, a contour, an outline, a texture, a variation, a continuity, a discontinuity, a raised portion, a recessed portion, a flat portion, a curved portion, and/or the like of a surface, a portion of the surface, a structure, a portion of the structure, and/or the like of the jet cartridge 14. It will be appreciated that the feature can include any other attribute that is visibly identifiable by the camera 30. The jet cartridge 14 can have a plurality of features, and the plurality of features can include the same features or a combination of different features as described above. FIGS. 7A-7C show a plurality of exemplary features 60 on the jet cartridge 14.

FIGS. 7A-7C depict images of portions of exemplary jet cartridges 14 as captured by the camera 30. The images of FIGS. 7A-7C are shown in a plane that is orthogonal to the dispensing axis A.

Each jet cartridge 14 can include a particular quantity, type, and/or arrangement of the one or more features 60. Thus, each jet cartridge 14 can have a pattern 114 that is visibly identifiable and/or recognizable by the camera 30. Each pattern 114 can include a particular arrangement of the one or more features 60 on the various surfaces of the jet cartridge 14. In some aspects, each jet cartridge 14 can have a unique, or a substantially unique, pattern 114 of the one or more features 60. Thus, each jet cartridge 14 can be differentiated from another jet cartridge 14.

A jet cartridge 14 may have a pattern 114 that are closer to some jet cartridges 14 than other jet cartridges 14. Some jet cartridges 14 that are manufactured by a first manufacturing process may have very similar patterns 114 to each other, but may have very different patterns 114 compared to other jet cartridges 14 that are manufactured by a second, different manufacturing process. Differences in patterns 114 can depend on differences in features 60 caused by manufacturing, for example, caused by use of different materials, different combinations of materials, different manufacturing tools utilized, different manufacturing constraints and tolerances, different manufacturing procedures, and/or the like.

Thus, a jet cartridge 14 manufactured by the first manufacturing process may be differentiated from a jet cartridge 14 manufactured by the second manufacturing process. Such differentiation can be determined by comparing the patterns 114 of features 60 between the different jet cartridges 14 using the camera 30. This could be an effective way of identifying and tracking jet cartridge use. This can allow for users to monitor and track duration of cartridge use to determine when a jet cartridge should be removed, replaced, cleaned, and/or the like. Such identification can also be used to identify physical defects of the jet cartridge 14, and particularly on the nozzle 40, that appear during use. In some aspects, this identification can be used to identify undesirable physical defects prior to use. such as a chipped nozzle or otherwise damaged cartridge face, so that the user can replace the defected jet cartridge 14.

The above identification can be used to discern between different types of jet cartridges 14. Identification of patterns 114 of features 60 can be used to differentiate between a new jet cartridge 14 and a previously-used jet cartridge 14. Such identification can help the user determine when the jet cartridge 14 may need to be repaired, replaced, cleaned, and/or the like. The identification can be used to differentiate between various jet cartridges 14 that are designed to be utilized with different types of the jet dispensers 10, different fluid materials to be dispensed, and/or different substrates. Such identification can help the user determine if the proper jet cartridge 14 is being utilized in the jet dispenser 10. The identification can be used to differentiate between jet cartridges 14 that are manufactured by different manufacturing processes as described above. Such identification can help the user determine if the jet cartridge 14 being used is a suitable component from the original equipment manufacturer (or a permissible substitute) or if, instead, the jet cartridge 14 is a less desirable or undesirable reproduction or counterfeit product.

To identify the jet cartridge 14 being used, the user can view the jet cartridge 14, for example, along the camera direction B, to identify the pattern of features 60 present on the jet cartridge 14. The user can view the jet cartridge 14 with the naked eye or with the help of an optical device. In some aspects, the user can view the jet cartridge 14 through the camera 30.

The above identification can be performed by a controller 100 in operable communication with the camera 30. Referring to FIG. 8, an exemplary system 90 is depicted. The system 90 can include the jet dispenser 10. The system 90 may include the camera 30 and the controller 100. The camera 30 may be configured to receive power from a power source 110 operably connected to the camera 30. The power source 110 can include a battery, a fuel cell, a solar panel, a wall outlet, and/or the like. The camera 30 can receive power directly from the power source 110 or, alternatively, via a controller 100. In some aspects, the jet dispenser identification system 92 can include the controller 100 and/or the power source 110. The system 90 can include the jet dispenser identification system 92 separate from the jet dispenser 10 (see FIG. 8). In some aspects, the jet dispenser identification system 92 can be operably connected with, and utilized with, the jet dispenser 10, a different jet dispenser, or a combination of different jet dispensers 10 and other suitable jet dispensers.

The controller 100 can include, or be disposed on or in, a computing device, such as a conventional server computer, a workstation, a desktop computer, a laptop, a tablet, network appliance, a personal digital assistant (PDA), a digital cellular phone, and/or other suitable computing device. The controller 100 may include a processor 102, a memory 104, a user interface 112, and/or the like. The memory 104 may be a single memory device or a plurality of memory devices including but not limited to read-only memory (ROM), random access memory (RAM), volatile memory, non-volatile memory, static random access memory (SRAM), dynamic random access memory (DRAM), flash memory, cache memory, or any other device capable of storing digital information. The memory 104 may also include a mass storage device (not shown) such as a hard drive, optical drive, tape drive, non-volatile solid state device or any other device capable of storing digital information.

The processor 102 may operate under the control of an operating system that resides in the memory 104. The processor 102 may include one or more devices selected from microprocessors, micro-controllers, digital signal processors, microcomputers, central processing units, field programmable gate arrays, programmable logic devices, state machines, logic circuits, analog circuits, digital circuits, and/or any other devices that manipulate signals (analog or digital) based on operational instructions that are stored in the memory 104.

The user interface 112 may be communicatively connected to the controller 100 to allow a system operator to interact with the controller 100. The user interface 112 may include one or more input/output devices. The user interface 112 may include a video monitor, alphanumeric displays, a touch screen, a speaker, and any other suitable audio and/or visual indicators capable of providing information to the system operator. The user interface 112 may include one or more input devices capable of accepting commands or input from the operator, such as an alphanumeric keyboard, a pointing device, keypads, pushbuttons, control knobs, microphones, and/or the like. In this way, the user interface 112 may enable manual initiation of system functions, for example, during set-up, calibration, inspection, and/or cleaning.

The processor 102 may be configured to control operation of the camera 30. The processor 102 may include a learning module 106 configured to be used to “teach” or train the processor 102 how to identify a jet cartridge 14. The processor 102 may include an operating module 108 that can utilize the “learned” information from the learning module 106 during operation of the jet dispenser 10 to identify a jet cartridge 14.

In aspects, the controller 100 and/or the processor 102 may not implement the learning module 106. In this aspect, implementation of the teaching or training functionality may be achieved in a separate computer system and the processor 102 may utilize the functionality of the operating module 108. In aspects, this separate computer system include any one or more of the features of the system 90, which may be a training implementation of the system 90.

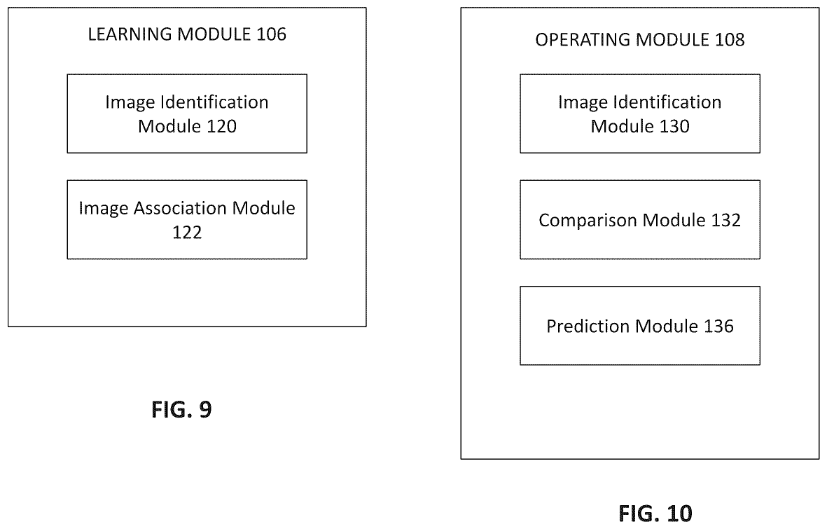

The learning module 106 may be used to train or teach the system 90 to identify images of various jet cartridges 14 and to associate the identified images with types of jet cartridges 14. Referring to FIG. 9, the learning module 106 may include an image identification module 120 and an image association module 122. The image identification module 120 can include instructions sent to the camera 30 to acquire an image, a plurality of images, a video, a plurality of videos, and/or the like of the jet cartridge 14 on the jet dispenser 10. The image identification module 120 can digitally identify the one or more features 60 on the acquired image, video, a plurality of images, a plurality of videos, and/or the like to discern a pattern of features 60. The image association module 122 can then associate the identified pattern of features 60 with the particular jet cartridge 14 that was inspected. The association can be with a name, a type, a serial number, a number, a manufacturing lot number, and/or another product identifier of the jet cartridge 14. The product identifier can be inputted into the controller 100 by the user via the user interface 112 or can be preprogrammed into software in the memory 104 of the controller 100. The association made by the image association module 122 can be stored in the memory 104. In some aspects, a plurality of jet cartridges 14 of the same product identifier can be used to teach the learning module 106. Thus, the learning module 106 can generate a plurality of associations of different identified patterns of features 60 for a single type of jet cartridge 14. The plurality of patterns of features 60 for the same identified type of jet cartridge 14 can be stored together, can be averaged together, or can be otherwise combined to generate a single pattern of features 60 that is similar to each of the patterns of features of each of the plurality of jet cartridges 14 of the same type that were observed. Similar learning processes can be utilized to generate associations for different types of jet cartridges 14.

After the system 90 has been “trained” as described above, the system 90 can be used to identify a jet cartridge 14 based on the stored training data. Referring to FIG. 10, during use of the system 90, the processor's operating module 108 can be utilized to identify the jet cartridge 14. The operating module 108 can include an image identification module 130, a comparison module 132, and a prediction module 136. The image identification module 130 can be configured to receive one or more images and/or videos from the camera 30 of the jet cartridge 14. Each image can include one or more features 60 arranged in a particular pattern that can be unique to the jet cartridge 14 or to a set of jet cartridges 14. The comparison module 132 can compare the identified features 60 in their respective pattern with stored features 60 and patterns in the memory 104 that were stored during the teaching phase by the learning module 106. The comparison module 132 can identify the closest-matching pattern of features 60 and the jet cartridge identifier associated with the closest-matching pattern. The prediction module 136 can then indicate to the user, for example, via the user interface 112, that the observed jet cartridge 14 is likely the same as the identified associated jet cartridge of the closest-matching pattern. The comparison module 132 and the prediction module 136 can provide the user a measurement of accuracy of the prediction. The accuracy measurement can be based on how similar the identified pattern is to the closest-matching pattern. The greater the similarity, the higher the accuracy indication can be.

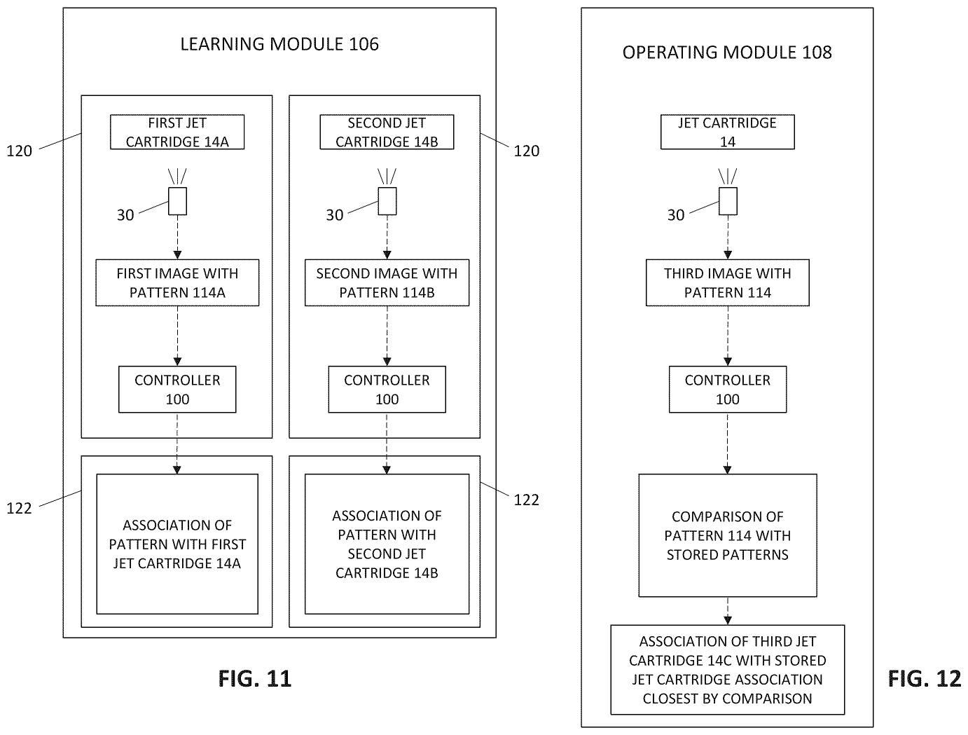

Referring to FIG. 11, an exemplary learning module 106 is depicted, respectively. During a learning process, such as described above, a first jet cartridge 14A can be observed by the camera 30. The camera 30 generates one or more images of the first jet cartridge 14A. Each image can include the one or more features 60 arranged in a particular first pattern 114A as observed by the camera 30. The generated images can be transmitted electronically to the controller 100, where the images may be saved into the memory 104. The first pattern 114A can then be associated with an identifier of the first jet cartridge 14A, such as a name, a type, a manufacturing lot number, and/or the like. The association can be saved to the memory 104. The above process can be repeated for any desired number of iterations. For example, a second jet cartridge 14B can be positioned to be observed by the camera 30. The camera 30 can generate an image of the second jet cartridge 14B, the image having the one or more features 60 arranged in a particular second pattern 114B. The second pattern 114B can be associated with an identifier of the second jet cartridge 14B, and the association can be saved to the memory 104. The first jet cartridge 14A and the second jet cartridge 14B may be associated with the same identifier (i.e., may be the same type of jet cartridge 14). Alternatively, the first jet cartridge 14A may be different from the second jet cartridge 14B and may be associated with a different cartridge identifier than the second jet cartridge 14B. It will be appreciated that the system 90 can be trained to identify and associate any suitable number of different jet cartridges 14A, 14B, . . . 14n, and the training and teaching can utilize any suitable number of iterations of each of the different jet cartridges 14A, 14B, . . . 14n.

Referring to FIG. 12, an exemplary process using the operating module 108 is depicted. The camera 30 can be directed to observe a jet cartridge 14. The camera 30 can take an image of the jet cartridge 14. The image can include one or more features 60 arranged in a particular pattern 114. The image with the pattern 114 can be transmitted to the controller 100 and stored in the memory 104. The processor 102 can compare the pattern 114 with one or more of the stored patterns in the memory 104 that were stored during the teaching process by the learning module 106. The comparison module 132 can compare parameters of the features 60 of the pattern 114 with stored patterns, for example, the first pattern 114A and/or the second pattern 114B. The comparable parameters can include: type, size, quantity, color, shape, orientation, and/or other characteristics of the one or more features 60. The comparable parameters can include relative positioning of multiple features 60. The comparable parameters can include location of one or more features 60 on the jet cartridge 14, and specifically on the nozzle 40. The prediction module 136 can select a stored pattern 114 that is closest to the identified pattern 114. Because each stored pattern 114 is associated with a particular jet cartridge 14, the prediction module 136 can then identify the associated jet cartridge of the selected closest-matching pattern 114.

In some aspects, the processor 102 may be configured to indicate to the user how similar the pattern 114 is with the closest-matching stored pattern. The processor 102 can provide a numerical percentage of similarity between the pattern 114 of the observed jet cartridge 14 and the closest-matching pattern 114. The more similar the two patterns 114 are, the higher the percentage will be. For example, if the system 90 has identified and stored data related to the first jet cartridge 14A, and, during operation, the system 90 observes the first jet cartridge 14A again, the system 90 can identify the observed jet cartridge correctly as the first jet cartridge 14A with a high percentage of certainty. In an ideal environment, the exact match would result in a 100% match; however, it should be understood that manufacturing tolerances, lighting, camera features, other hardware, software, and other components in or around the system 90 can interfere with the identification process, and that the accuracy of the identification may not be exact.

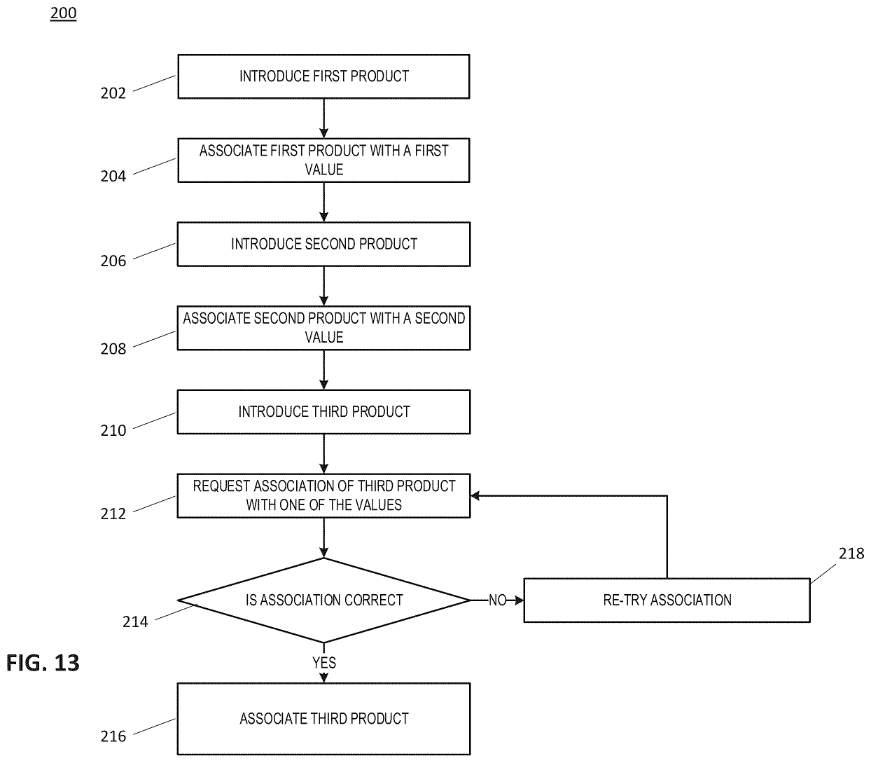

The learning module 106 may include a machine learning component to allow the processor 102 to improve accuracy in identifying and matching jet cartridges 14 based on their observed patterns 114. The teaching of the system 90 can include user-assisted guidance to better train the processor 102. Referring to FIG. 13, an exemplary training process 200 is depicted. The training process 200 illustrated in FIG. 13 and described below may include any one or more other features, components, arrangements, and/or the like as described herein. It should be noted that the aspects of training process 200 may be performed in a different order consistent with the aspects described herein. Moreover, training process 200 may be modified to have more or fewer processes consistent with the various aspects disclosed herein.

In step 202, a product can be introduced into the system 90 for identification. The product can include a jet cartridge 14. The camera 30 can be configured to generate one or more images of the jet cartridge 14 and of the features 60 thereon as described throughout this application. The jet cartridge 14 can be a first jet cartridge 14A. It will be appreciated that numerical identification of jet cartridges is used for relative description of the embodiments and processes throughout this application and are not intended to be limiting to particular jet cartridges. The processor 102 can store a first pattern 114A of the features 60 of the first jet cartridge 14A. During step 204, the processor 102 can associate the identified pattern 114 of features 60 with an identifier of the first jet cartridge 14A. The identifier can be inputted by the user or may be preprogrammed into the controller 100.

In step 206, a second product is introduced that is different from the first product. The second product can be a second jet cartridge 14B. In step 208, the system 90 can receive an image from the camera 30 of the second jet cartridge 14B and associate an identified second pattern 114B of features 60 with an identifier of the second jet cartridge 14B. At this point in the process 200, the system 90 is trained to identify at least the first jet cartridge 14A and the second jet cartridge 14B.

In step 210, a third product can be introduced to the system 90 such that the camera 30 is configured to identify and generate an image thereof. The third product can be the first jet cartridge 14A, the second jet cartridge 14B, or another jet cartridge 14. The processor 102 identifies the features 60 and the pattern 114 of the features 60 of the third product.

In step 212, the processor 102 can use the operating module 108 as described above to attempt to identify the third product and to match it to the closest-matching stored product. The processor 102 can provide a prediction to the user of which product identifier associated with the closest-matching pattern 114 likely corresponds to the third product. The processor 102 can also provide an accuracy measurement, as described above, that provides the user an indication of how close the third product's pattern 114 is to the closest-matching pattern 114. The accuracy measurement can be a percentage of similarity between the third product's pattern 114 and the closest-matching pattern 114.

In step 214, the user indicates to the system 90 if the prediction is correct. If the prediction module 136 properly identified the third product, the user indicates as such (e.g., via the user interface 112), and the process 200 proceeds to step 216. In step 216, the processor 102 associates the pattern of the third product with the properly identified product (e.g., with the first or second product) and stores the association in the memory 104. If the association is incorrect, the user indicates as such, and the process 200 proceeds to step 218. In step 218, the processor 102 can predict a different association than what was done in step 212. From step 218, the process 200 can return to step 212 and once again attempt to identify the proper association.

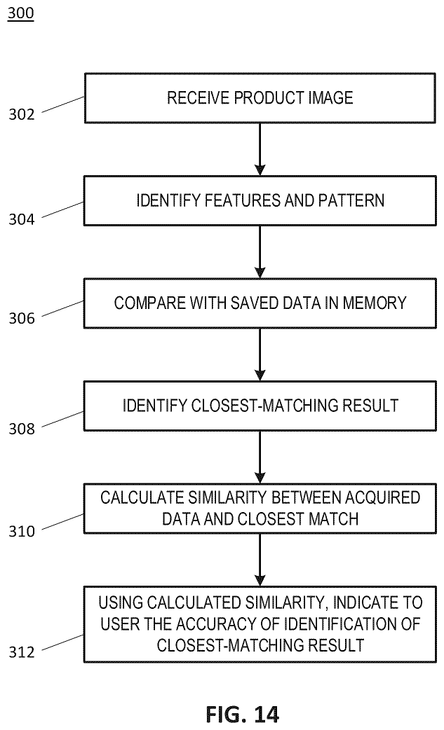

FIG. 14 depicts an exemplary process 300 of utilizing the trained system 90 to identify a product. The product for identification can be a jet cartridge 14, such as described throughout this application. The process 300 illustrated in FIG. 13 and described below may include any one or more other features, components, arrangements, and/or the like as described herein. It should be noted that the aspects of the process 300 may be performed in a different order consistent with the aspects described herein. Moreover, the process 300 may be modified to have more or fewer processes consistent with the various aspects disclosed herein.

In step 302, the system 90 can be configured to observe the jet cartridge 14. The observation can be done by the camera 30. The camera 30 can acquire one or more images of the jet cartridge 14 and transmit the acquired images to the controller 100.

In step 304, the system 90 can identify the one or more features 60 on the acquired image or images. The system 90 can detect a pattern 114 of the features 60.

In step 306, the system 90 can compare the identified pattern 114 with one or more patterns (e.g., patterns 114A, 114B, . . . , 114n) that were saved to the memory 104 during the teaching process 200 or a similar process.

In step 308, using the comparison described above, the system 90 can identify a saved image that has a pattern that is closest to the identified pattern 114. The system 90 can compare characteristics of the pattern to identify the closest match. The comparison can look at features 60, specifically, feature type, size, quantity, color, shape, orientation, and the like, as well as relative positioning of multiple features 60 and/or location of the one or more features 60 on the acquired image.

In step 310, the system 90 can calculate the similarity between the pattern 114 and its features 60 and the closest-matching pattern from the memory 104. In step 312, the calculated similarity can be displayed to the user. The similarity can be portrayed as a percentage. The percentage can indicate to the user how close the closest-matching pattern is to the acquired pattern. The greater the similarity, the higher the accuracy percentage can be. For example, if the pattern 114 is exactly the same as the closest-matching pattern in the memory 104, the accuracy percentage can be 100% (or slightly less than 100% if accounting for manufacturing tolerances, optical distinctions, error, etc.). The user can determine if the accuracy percentage depicted is sufficiently high to trust the identification of the system 90.

The user can rely on various acceptable threshold ranges for accuracy. For example, if the accuracy is between 90% and 100%, the user can be sure that the prediction is likely correct: however, if the accuracy is below 30%, the user may be unsure of the accuracy of the prediction. The accuracy measurement can also be helpful to a user to determine wear of the jet cartridge 14. For example, if a particular jet cartridge 14 is identified as having a 90% match to a saved data point when the jet cartridge 14 is new, and the same jet cartridge 14, after a set duration of use, is later identified as having an 80% match to the same saved data point as before, the change in accuracy could be indicative of change in the pattern 114 over time during use. For example, the jet cartridge 14 can receive more or different features 60 during use, and/or the existing features 60 can be altered during use. Such observation can facilitate the user's ability to determine how quickly a particular component wears down and when to replace or clean the component.

It should be appreciated that the above ranges are exemplary and are not intended to limit the application of any of the embodiments described herein.

As described above, an advantage of utilizing a system 90 to identify components can include identification of counterfeit products. In some aspects, counterfeit products can include different features 60 and/or can include different patterns 114 of features 60 compared to original manufacturers equipment (OEM) products. To improve the ability to discern between OEM products (or other intended products) and counterfeit products, the OEM products can be manufactured to include one or more features 60 that are indicative of original (or otherwise approved) parts. For example, an OEM jet cartridge 14 can include a protection feature thereon that is included only in OEM jet cartridges 14 but is absent from counterfeit jet cartridges. The protection feature may include any one of the features 60 described herein. The protection feature should be known to the production of the OEM parts and/or to the user of the jet dispenser 10 and/or the system 90. Thus, during the identification processes described throughout this application, the system 90 may be configured to detect the protection feature during the steps of detecting the features 60. If the protection feature is present, the processor 102 can indicate to the user that the product with the protection feature is an OEM product (or an otherwise acceptable product). If the protection feature is not detected, the processor 102 can indicate to the user that the product may be counterfeit.

The protection feature can include any of the features 60 described above. In some aspects, the protection feature can include a sequence of particular shapes, numbers, letter, symbols, or the like. In some aspects, the protection feature can include a barcode that can be readable by a barcode reader (not shown). In some aspects, the barcode reader can be a distinct component in the system 90. In other aspects, the barcode reading capability can be incorporated in the camera 30 or in the software of the controller 100.

The system 90, which may include the learning module 106, the operating module 108, the training process 200, the process 300, and/or the like may be implemented in some aspects as a neural network that may include a network of neurons, a circuit of neurons, an artificial neural network, artificial neurons, artificial nodes, and/or the like. The system 90 may include a plurality of neurons with connections that may be modeled with weights, which may reflect an excitatory connection, an inhibitory connection, and/or the like. The system 90 may receive inputs that may be modified by a weight and summed, which may be a linear combination. The inputs may include one or more of the images, the product identifier, and/or the like. The system 90 may generate outputs consistent with the training process 200, the process 300, and/or the like as described above. In particular, the system 90 may generate outputs consistent with the step 310, the step 312, and/or the like.

The system 90, which may include the learning module 106, the operating module 108, the training process 200, the process 300, and/or the like may be trained via a dataset as described herein utilizing a self-learning resulting from experience as it relates to the images described herein. The system 90 may implement information processing paradigms for image recognition, image analysis, and/or the like. The system 90 may implement the artificial neurons in an artificial neural network (ANN), a simulated neural network (SNN), and/or the like that may be an interconnected group of artificial neurons that we use a mathematical model, a computational model, and/or the like for information processing based on a connectionistic approach to computation for implementation in the learning module 106, the operating module 108, and/or the like. In particular, the system 90 may implement classification including pattern recognition, pattern detection, and/or the like for pattern recognition, visualization, and/or the like for implementation in the learning module 106, the operating module 108, and/or the like.

The following are a number of nonlimiting EXAMPLES of aspects of the disclosure.

One EXAMPLE includes: a jet dispenser identification system includes a camera configured to acquire a digital image of a jet dispenser. The jet dispenser identification system in addition includes a controller having a memory and a processor, the processor configured to: identify, on the digital image of the jet dispenser, an identified pattern of features present on the jet dispenser: compare the identified pattern with a stored pattern, the stored pattern being stored in the memory: calculate a similarity between the identified pattern and the stored pattern; and provide an identifier value associated with the stored pattern.

The above-noted EXAMPLE may further include any one or a combination of more than one of the following EXAMPLES: The system of the above-noted EXAMPLE where the identifier value may include at least one of the following associated with the jet dispenser cartridge: a product name, a product type, a product serial number, a product number, and a product manufacturing lot number. The system of the above-noted EXAMPLE where the processor is configured to compare the identified pattern with a plurality of stored patterns and calculate the similarity between the identified pattern and each of the plurality of stored patterns, the processor being further configured to select one of the plurality of stored patterns, the one of the plurality of stored patterns being most similar to the identified pattern out of the plurality of stored patterns. The system of the above-noted EXAMPLE where the processor is configured to implement a neural network to compare the identified pattern with a plurality of stored patterns and calculate the similarity between the identified pattern and each of the plurality of stored patterns, the processor being further configured to implement the neural network to select one of the plurality of stored patterns, the one of the plurality of stored patterns being most similar to the identified pattern out of the plurality of stored patterns. The system of the above-noted EXAMPLE where the system is configured to be in wired communication with a jet dispenser configured to receive a fluid material therein. The system of the above-noted EXAMPLE where the system is configured to be in wireless communication with a jet dispenser configured to receive a fluid material therein. The dispensing system of the above-noted EXAMPLE.

One EXAMPLE includes: a method includes introducing a first component to an input device in electronic communication with the controller, the first component having a first feature thereon. The method in addition includes associating, via the processor, the first feature with a first identifier associated with the first component. The method moreover includes storing the association of the first feature with the first identifier in the memory. The method also includes introducing a second component to the input device, the second component having a second feature. The method further includes associating, via the processor, the second feature with a second identifier associated with the second component. The method in addition includes storing the association of the second feature with the second identifier in the memory.

The above-noted EXAMPLE may further include any one or a combination of more than one of the following EXAMPLES: The method of the above-noted EXAMPLE where the input device may include a camera configured to acquire a digital image of the first and second components. The method of the above-noted EXAMPLE where the first and second identifiers may include at least one of the following associated with the first and second components: product names, product types, product serial numbers, product numbers, and product manufacturing lot numbers. The method of the above-noted EXAMPLE may include: introducing a third component to the input device, the third component having a third feature: comparing the third feature of the third component to the first feature of the first component and to the second feature of the second component; and receiving a prediction from the processor of which of the first component and the second component is more similar to the third component. The method of the above-noted EXAMPLE may include indicating to the processor whether the prediction is correct.

One EXAMPLE includes: a method includes actuating the camera to acquire an image of the jet cartridge. The method in addition includes identifying a pattern of features on the jet cartridge that are visible on the acquired image. The method moreover includes comparing the identified pattern with a plurality of stored patterns in the memory. The method also includes actuating the processor to select one of the plurality of stored patterns, the selected one of the plurality of stored patterns being most similar to the identified pattern out of the plurality of stored patterns. The method further includes displaying an identifier associated with the selected one of the plurality of stored patterns.

The above-noted EXAMPLE may further include any one or a combination of more than one of the following EXAMPLES: The method of the above-noted EXAMPLE may include displaying a measurement of similarity between the identified pattern and the selected one of the plurality of stored patterns. The method of the above-noted EXAMPLE where the identifier may include at least one of the following: a product name, a product type, a product serial number, a product number, and a product manufacturing lot number. The method of the above-noted EXAMPLE where the pattern of features includes a barcode. The method of the above-noted EXAMPLE where the comparing and the actuating further may include implementing a neural network. The method of the above-noted EXAMPLE may include displaying an accuracy value associated with the identifier.

One EXAMPLE includes: a manufacturing system includes a dispenser configured to receive the fluid material therein, the dispenser having a dispenser component operably connected thereto, the dispenser component being configured to receive the fluid material from the dispenser and having a nozzle configured to discharge the fluid material. The manufacturing system in addition includes a camera configured to acquire a digital image of the dispenser. The manufacturing system moreover includes a controller having a memory and a processor, the processor configured to: identify, on the digital image of the dispenser, an identified pattern of features present on the dispenser: compare the identified pattern with a stored pattern, the stored pattern being stored in the memory: calculate a similarity between the identified pattern and the stored pattern; and provide an identifier value associated with the stored pattern.

The above-noted EXAMPLE may further include any one or a combination of more than one of the following EXAMPLES: The manufacturing system of the above-noted EXAMPLE where the identifier value may include at least one of the following associated with the dispenser component: a product name, a product type, a product serial number, a product number, and a product manufacturing lot number. The manufacturing system of the above-noted EXAMPLE where the processor is configured to compare the identified pattern with a plurality of stored patterns and calculate the similarity between the identified pattern and each of the plurality of stored patterns, the processor being further configured to select one of the plurality of stored patterns, the one of the plurality of stored patterns being most similar to the identified pattern out of the plurality of stored patterns. The manufacturing system of the above-noted EXAMPLE where the processor is configured to implement a neural network to compare the identified pattern with a plurality of stored patterns and calculate the similarity between the identified pattern and each of the plurality of stored patterns, the processor being further configured to implement the neural network to select one of the plurality of stored patterns, the one of the plurality of stored patterns being most similar to the identified pattern out of the plurality of stored patterns.

One EXAMPLE includes: a method includes introducing a first component to an input device in electronic communication with the controller, the first component having a first feature thereon. The method in addition includes associating, via the processor, the first feature with a first identifier associated with the first component. The method moreover includes storing the association of the first feature with the first identifier in the memory. The method also includes introducing a second component to the input device, the second component having a second feature. The method further includes associating, via the processor, the second feature with a second identifier associated with the second component. The method in addition includes storing the association of the second feature with the second identifier in the memory.

The above-noted EXAMPLE may further include any one or a combination of more than one of the following EXAMPLES: The method of the above-noted EXAMPLE where the input device may include a camera configured to acquire a digital image of the first and second components. The method of the above-noted EXAMPLE where the first and second identifiers may include at least one of the following associated with the first and second components: product names, product types, product serial numbers, product numbers, and product manufacturing lot numbers. The method of the above-noted EXAMPLE may include: introducing a third component to the input device, the third component having a third feature: comparing the third feature of the third component to the first feature of the first component and to the second feature of the second component; and receiving a prediction from the processor of which of the first component and the second component is more similar to the third component. The method of the above-noted EXAMPLE may include indicating to the processor whether the prediction is correct.

One EXAMPLE includes: a method includes actuating the camera to acquire an image of the dispenser component. The method in addition includes identifying a pattern of features on the dispenser component that are visible on the acquired image. The method moreover includes comparing the identified pattern with a plurality of stored patterns in the memory. The method also includes actuating the processor to select one of the plurality of stored patterns, the selected one of the plurality of stored patterns being most similar to the identified pattern out of the plurality of stored patterns. The method further includes displaying an identifier associated with the selected one of the plurality of stored patterns.

The above-noted EXAMPLE may further include any one or a combination of more than one of the following EXAMPLES: The method of the above-noted EXAMPLE may include displaying a measurement of similarity between the identified pattern and the selected one of the plurality of stored patterns. The method of the above-noted EXAMPLE where the identifier may include at least one of the following: a product name, a product type, a product serial number, a product number, and a product manufacturing lot number. The method of the above-noted EXAMPLE where the pattern of features includes a barcode. The method of the above-noted EXAMPLE where the comparing and the actuating further may include implementing a neural network. The method of the above-noted EXAMPLE may include displaying an accuracy value associated with the identifier.

While systems and methods have been described in connection with the various embodiments of the various figures, it will be appreciated by those skilled in the art that changes could be made to the embodiments without departing from the broad inventive concept thereof. It is understood, therefore, that this disclosure is not limited to the particular embodiments disclosed, and it is intended to cover modifications within the spirit and scope of the disclosure as defined by the claims.

The term “plurality,” as used herein, means more than one. The singular forms “a.” “an,” and “the” include the plural reference, and reference to a particular numerical value includes at least that particular value, unless the context clearly indicates otherwise. Thus, for example, a reference to “a material” is a reference to at least one of such materials and equivalents thereof known to those skilled in the art, and so forth.

When values are expressed as approximations by use of the antecedent “about.” it will be understood that the particular value forms another embodiment. In general, use of the term “about” indicates approximations that can vary depending on the desired properties sought to be obtained by the disclosed subject matter and is to be interpreted in the specific context in which it is used, based on its function, and the person skilled in the art will be able to interpret it as such. In some cases, the number of significant figures used for a particular value may be one non-limiting method of determining the extent of the word “about.” In other cases, the gradations used in a series of values may be used to determine the intended range available to the term “about” for each value. Where present, all ranges are inclusive and combinable. That is, reference to values stated in ranges includes each and every value within that range. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

When a list is presented, unless stated otherwise, it is to be understood that each individual element of that list, and every combination of that list, is a separate embodiment. For example, a list of embodiments presented as “A, B, or C” is to be interpreted as including the embodiments, “A,” “B,” “C,” “A or B,” “A or C,” “B or C,” or “A, B, or C.”

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more examples or that one or more examples necessarily include these features, elements and/or steps. The terms “comprising.” “including.” “having.” and the like are synonymous and are used inclusively, in an open-ended fashion, and do not exclude additional elements, features, acts, operations, and so forth.

While certain examples have been described, these examples have been presented by way of example only and are not intended to limit the scope of the inventions disclosed herein. Thus, nothing in the foregoing description is intended to imply that any particular feature, characteristic, step, module, or block is necessary or indispensable. Indeed, the novel methods and systems described herein may be embodied in a variety of other forms; furthermore, various omissions, substitutions, and changes in the form of the methods and systems described herein may be made without departing from the spirit of the inventions disclosed herein. The accompanying claims and their equivalents are intended to cover such forms or modifications as would fall within the scope and spirit of certain of the inventions disclosed herein.

1. A jet dispenser identification system, the jet dispenser identification system comprising:
a camera configured to acquire a digital image of a jet dispenser; and
a controller having a memory and a processor, the processor configured to:
identify, on the digital image of the jet dispenser, an identified pattern of features present on the jet dispenser;
compare the identified pattern with a stored pattern, the stored pattern being stored in the memory;
calculate a similarity between the identified pattern and the stored pattern; and
provide an identifier value associated with the stored pattern.

2. The jet dispenser identification system of claim 1, wherein the identifier value comprises at least one of the following associated with the jet dispenser: a product name, a product type, a product serial number, a product number, and a product manufacturing lot number.

3. The jet dispenser identification system of claim 1, wherein the processor is configured to compare the identified pattern with a plurality of stored patterns and calculate the similarity between the identified pattern and each of the plurality of stored patterns, the processor being further configured to select one of the plurality of stored patterns, the one of the plurality of stored patterns being most similar to the identified pattern out of the plurality of stored patterns.

4. The jet dispenser identification system of claim 1, wherein the processor is configured to implement a neural network to compare the identified pattern with a plurality of stored patterns and calculate the similarity between the identified pattern and each of the plurality of stored patterns, the processor being further configured to implement the neural network to select one of the plurality of stored patterns, the one of the plurality of stored patterns being most similar to the identified pattern out of the plurality of stored patterns.

5. The jet dispenser identification system of claim 1, wherein the system is configured to be in wired communication with a jet dispenser configured to receive a fluid material therein.

6. The jet dispenser identification system of claim 1, wherein the system is configured to be in wireless communication with a jet dispenser configured to receive a fluid material therein.

7. A dispensing system for dispensing a fluid material onto a substrate, the dispensing system comprising:
a jet dispenser configured to receive the fluid material therein, the jet dispenser having a jet cartridge operably connected thereto, the jet cartridge being configured to receive the fluid material and having a nozzle configured to discharge the fluid material; and
the jet dispenser identification system of claim 1.

8. A method of training a neural network to identify a component out of a stored list of components, the neural network being stored on a memory of a controller and operable by a processor on the controller, the method comprising:
introducing a first component to an input device in electronic communication with the controller, the first component having a first feature thereon;
associating, via the processor, the first feature with a first identifier associated with the first component;
storing the association of the first feature with the first identifier in the memory;
introducing a second component to the input device, the second component having a second feature;
associating, via the processor, the second feature with a second identifier associated with the second component; and
storing the association of the second feature with the second identifier in the memory.

9. The method of claim 8, wherein the input device comprises a camera configured to acquire a digital image of the first and second components.

10. The method of claim 8, wherein the first and second identifiers comprise at least one of the following associated with the first and second components: product names, product types, product serial numbers, product numbers, and product manufacturing lot numbers.

11. The method of claim 8, further comprising:
introducing a third component to the input device, the third component having a third feature;
comparing the third feature of the third component to the first feature of the first component and to the second feature of the second component; and
receiving a prediction from the processor of which of the first component and the second component is more similar to the third component.

12. The method of claim 11, further comprising indicating to the processor whether the prediction is correct.

13. A method of identifying a jet cartridge in a dispensing system, the dispensing system including the jet cartridge, a camera, and a controller having a processor and a memory, the method comprising:
actuating the camera to acquire an image of the jet cartridge;
identifying a pattern of features on the jet cartridge that are visible on the acquired image;
comparing the identified pattern with a plurality of stored patterns in the memory;
actuating the processor to select one of the plurality of stored patterns, the selected one of the plurality of stored patterns being most similar to the identified pattern out of the plurality of stored patterns; and
displaying an identifier associated with the selected one of the plurality of stored patterns.

14. The method of claim 13, further comprising displaying a measurement of similarity between the identified pattern and the selected one of the plurality of stored patterns.

15. The method of claim 13, wherein the identifier comprises at least one of the following: a product name, a product type, a product serial number, a product number, and a product manufacturing lot number.

16. The method of claim 13, wherein the pattern of features includes a barcode.

17. The method of claim 13, wherein the comparing and the actuating further comprise implementing a neural network.

18. The method of claim 13, further comprising displaying an accuracy value associated with the identifier.

19. A manufacturing system for dispensing a fluid material, the manufacturing system comprising:
a dispenser configured to receive the fluid material therein, the dispenser having a dispenser component operably connected thereto, the dispenser component being configured to receive the fluid material from the dispenser and having a nozzle configured to discharge the fluid material,
a camera configured to acquire a digital image of the dispenser; and
a controller having a memory and a processor, the processor configured to:
identify, on the digital image of the dispenser, an identified pattern of features present on the dispenser;
compare the identified pattern with a stored pattern, the stored pattern being stored in the memory;
calculate a similarity between the identified pattern and the stored pattern; and
provide an identifier value associated with the stored pattern.

20. The manufacturing system of claim 19, wherein the identifier value comprises at least one of the following associated with the dispenser component: a product name, a product type, a product serial number, a product number, and a product manufacturing lot number.

21. The manufacturing system of claim 19, wherein the processor is configured to compare the identified pattern with a plurality of stored patterns and calculate the similarity between the identified pattern and each of the plurality of stored patterns, the processor being further configured to select one of the plurality of stored patterns, the one of the plurality of stored patterns being most similar to the identified pattern out of the plurality of stored patterns.

22. The manufacturing system of claim 19, wherein the processor is configured to implement a neural network to compare the identified pattern with a plurality of stored patterns and calculate the similarity between the identified pattern and each of the plurality of stored patterns, the processor being further configured to implement the neural network to select one of the plurality of stored patterns, the one of the plurality of stored patterns being most similar to the identified pattern out of the plurality of stored patterns.

23. A method of training a neural network to identify a component out of a stored list of components, the neural network being stored on a memory of a controller and operable by a processor on the controller, the method comprising:
introducing a first component to an input device in electronic communication with the controller, the first component having a first feature thereon;
associating, via the processor, the first feature with a first identifier associated with the first component;
storing the association of the first feature with the first identifier in the memory;
introducing a second component to the input device, the second component having a second feature;
associating, via the processor, the second feature with a second identifier associated with the second component; and
storing the association of the second feature with the second identifier in the memory.

24. The method of claim 23, wherein the input device comprises a camera configured to acquire a digital image of the first and second components.

25. The method of claim 23, wherein the first and second identifiers comprise at least one of the following associated with the first and second components: product names, product types, product serial numbers, product numbers, and product manufacturing lot numbers.

26. The method of claim 23, further comprising:
introducing a third component to the input device, the third component having a third feature;
comparing the third feature of the third component to the first feature of the first component and to the second feature of the second component; and
receiving a prediction from the processor of which of the first component and the second component is more similar to the third component.

27. The method of claim 26, further comprising indicating to the processor whether the prediction is correct.

28. A method of identifying a dispenser component in a manufacturing system, the manufacturing system including the dispenser component, a camera, and a controller having a processor and a memory, the method comprising:
actuating the camera to acquire an image of the dispenser component;
identifying a pattern of features on the dispenser component that are visible on the acquired image;
comparing the identified pattern with a plurality of stored patterns in the memory;
actuating the processor to select one of the plurality of stored patterns, the selected one of the plurality of stored patterns being most similar to the identified pattern out of the plurality of stored patterns; and
displaying an identifier associated with the selected one of the plurality of stored patterns.

29. The method of claim 28, further comprising displaying a measurement of similarity between the identified pattern and the selected one of the plurality of stored patterns.

30. The method of claim 28, wherein the identifier comprises at least one of the following: a product name, a product type, a product serial number, a product number, and a product manufacturing lot number.

31. The method of claim 28, wherein the pattern of features includes a barcode.

32. The method of claim 28, wherein the comparing and the actuating further comprise implementing a neural network.

33. The method of claim 28, further comprising displaying an accuracy value associated with the identifier.
